(19) United States
(12) Patent Application Publication
(10) Pub. No.: US 2021/0109168 A1
(43) Pub. Date: Apr. 15, 2021

(54) MAGNETO-OPTICAL MEASUREMENT APPARATUS

(71) Applicant: TIANMA JAPAN, LTD., Kawasaki (JP)

(72) Inventor: Nobuya SEKO, Kawasaki (JP)

(73) Assignee: TIANMA JAPAN, LTD., Kawasaki (JP)

(21) Appl. No.: 17/060,214

(22) Filed: Oct. 1, 2020

(30) Foreign Application Priority Data
Oct. 11, 2019 (JP) 2019-187428

(51) Int. Cl. G01R 33/032

(52) U.S. Cl. CPC G01R 33/0325

(57) ABSTRACT

A magneto-optical measurement apparatus includes a light source, a thin-film sensor including a magnetic film and reflecting light from the light source, a magnetic field generation device applying a magnetic field to the thin-film sensor, and a controller. The magnetic field generation device is configured to alternately supply a positive magnetic field and a negative magnetic field to the thin-film sensor. The controller is configured to measure the amount of light reflected by the thin-film sensor under the positive magnetic field, measure the amount of light reflected by the thin-film sensor under the negative magnetic field, determine one or more regression formulae from the values measured under the positive magnetic field and the values measured under the negative magnetic field, and determine a predetermined output value based on the one or more regression formulae.

### CROSS-REFERENCE TO RELATED APPLICATIONS

This non-provisional application claims priority under 35 U.S.C. § 119(a) on Patent Application No. 2019-187428 filed in Japan on Oct. 11, 2019, the entire content of which is hereby incorporated by reference.

### BACKGROUND

This disclosure relates to a magneto-optical measurement apparatus.

A measurement technology that amplifies and detects a magneto-optical effect of a thin film sensor having an optical interferometric structure has been proposed to achieve highly sensitive, highly accurate, and widely applicable measurement. The optical interferometric structure is attained by stacking a magnetic layer, an optical interference layer, and a reflective layer. For example, JP 2017-172993 A discloses a gas (hydrogen) sensor utilizing this measurement technology and JP 6368880 B discloses a polarimeter utilizing this measurement technology. These patent documents each provide embodiments that apply a cyclically alternating magnetic field to the thin-film sensor to describe a method of detecting a gas or optical rotation using a loop of output (the amount of light or the polarization angle) by Kerr effect.

### SUMMARY

An aspect of this disclosure is a magneto-optical measurement apparatus including: a light source; a thin-film sensor including a magnetic film and being configured to reflect light from the light source; a magnetic field generation device configured to apply a magnetic field to the thin-film sensor; and a controller. The magnetic field generation device is configured to alternately supply a positive magnetic field and a negative magnetic field to the thin-film sensor to alternately cause positive magnetization and negative magnetization having equal magnitude but opposite directions in the magnetic film. The controller is configured to: measure the amount of light reflected by the thin-film sensor at a plurality of times under the positive magnetic field; measure the amount of light reflected by the thin-film sensor at a plurality of times under the negative magnetic field; determine one or more regression formulae from the values measured under the positive magnetic field at the plurality of times and the values measured under the negative magnetic field at the plurality of times; and determine a specific output value based on the one or more regression formulae.

It is to be understood that both the foregoing general description and the following detailed description are exemplary and explanatory and are not restrictive of this disclosure.

### BRIEF DESCRIPTION OF THE DRAWINGS

FIG. 1 schematically illustrates a configuration example of a magneto-optical measurement apparatus;

FIG. 2 illustrates an example of a laminate structure of a thin-film sensor;

FIG. 3 schematically illustrates an example of temporal variation of excitation current in a magnetic field generation device;

FIG. 4 schematically illustrates a relation between alternating magnetic fields and the amount of reflected light;

FIG. 5 illustrates an example of the relation between the Kerr output value and the polarization angle of incident light;

FIG. 6 provides an example of output of a lock-in amplifier converted by an ADC into a digital signal;

FIG. 7 illustrates measurement periods to be excluded and measurement periods to be used for the controller to calculate regression formulae;

FIG. 8 illustrates examples of the relations between valid measured values and regression formulae;

FIG. 9 illustrates an example of values actually measured under a positive magnetic field, values actually measured under a negative magnetic field, values expected to be measured in zero magnetization that are calculated based on an appropriate Kerr output value, and a regression formula therefor;

FIG. 10 illustrates an example of temporal variation of driving current for a light source;

FIG. 11 provides comparison results of output of the light source in the cases where the light source rested for a sufficiently long time is turned on and provided with different DC lighting (aging) periods between 0 seconds and 10 seconds before being switched to the pulsed constant current driving (at a duty of 50%);

FIG. 12 illustrates an example of temporal variation of the relative amount of light when a non-lighted semiconductor light source is lighted and driven by a constant current; and

FIG. 13 illustrates an example of temporal variation of the relative amount of light when a semiconductor light source is controlled so that the values acquired from a photodetector will be a fixed value.

### EMBODIMENTS

Hereinafter, embodiments of this disclosure will be described with reference to the accompanying drawings. It should be noted that the embodiments are merely examples to realize the idea of this disclosure and not to limit the technical scope of this disclosure.

### Overview

The magneto-optical measurement described herein alternately applies a positive magnetic field and a negative magnetic field having opposite directions to a thin-film sensor (sensing element) including a magnetic film (magnetic layer) to alternately cause positive magnetization and negative magnetization in the opposite directions but of equal magnitude in the magnetic film. The measurement measures the amount of the light reflected by the thin-film sensor under the positive magnetic field and the amount of the light reflected by the thin film sensor under the negative magnetic field and obtains an output value (Kerr output value) of the magnetic Kerr effect from the measured values.

The Kerr output value in this disclosure is defined as the ratio of the varied amount of the reflected light after the magnetization of the thin-film sensor is changed to the amount of the reflected light when the magnetization of the thin-film sensor is zero, instead of the absolute value of the varied amount of the reflected light. The proportion of the reflected light does not change even if the amount of incident light changes and therefore, the measurement is not affected by the absolute value of the amount of light from the light source.

However, to attain a zero-magnetization state, demagnetization process is necessary because magnetic materials generally have residual magnetization. It is known that the Kerr effect under a positive magnetization and the Kerr effect under a negative magnetization occur symmetrically with respect to the Kerr effect under zero magnetization in the method used in this disclosure. Accordingly, the average of the amounts of reflected light when the same intensity of positive and negative magnetization in the opposite directions are applied becomes equal to the amount of reflected light under the zero-magnetization state. For this reason, the Kerr output value can be obtained by measuring the amounts of reflected light when the same magnitude of positive and negative magnetization in the opposite directions are applied, namely, under a positive magnetic field and a negative magnetic field.

However, it is impossible to simultaneously perform measurement under the positive magnetic field and measurement under the negative magnetic field; a time lag occurs therebetween. Meanwhile, the actual reflected light to be measured is extremely weak compared to the incident light (approximately 0.01% of the amount of incident light) because of the multireflection and interference within the laminate of the thin-film sensor. To attain a high S/N ratio by reducing the effect of the noise such as the external light, synchronized measurement utilizing a lock-in amplifier can be employed. The lock-in amplifier has a time constant because of its configuration and therefore, a certain time is required until the measurement result is stabilized after the magnetic field is reversed, for example. This could be another cause to generate a time lag between measurement under different magnetic fields.

Independence from the amount of light from the light source achieved by taking the proportion of the amount of reflected light is premised on that the amounts of light from the light source are the same in the measurement in the positive and the negative magnetic fields. For more accurate measurement, it is important that the amount of light from the light source is constant during a period including the measurement under the positive magnetic field and the measurement under the negative magnetic field. The magneto-optical measurement described herein uses a semiconductor light source that emits light having a sharp spectrum, such as a laser diode (LD) or a light-emitting diode (LED). The semiconductor light source exhibits a large variation in the amount of light for a while after being lighted because of its characteristics; it has to be lighted continuously for a comparatively long time until its output is sufficiently stabilized.

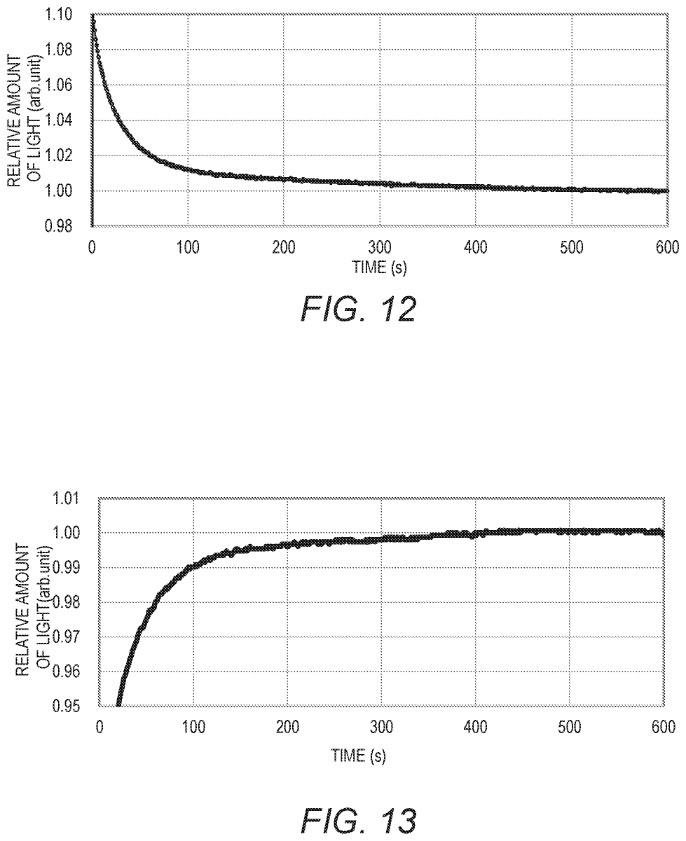

FIG. 12 illustrates an example of temporal variation of the relative amount of light when a non-lighted semiconductor light source is lighted and driven by a constant current. The relative amount of light starts falling immediately after the light source is lighted and gradually approaches a certain value. It takes time until the amount of light reaches the certain value and becomes stable. Furthermore, the amount of light sharply changes (falls) immediately after the light source is lighted. Although this example is about the amount of light in the case where the light source is driven by a direct constant current, the amount of light in the case where the light source is driven by a pulsed constant current exhibits similar variation.

A semiconductor light source can be operated with a photodetector for monitoring the output of the light source. The semiconductor light source can be controlled so that the values acquired from the photodetector will be a fixed value. FIG. 13 illustrates an example of temporal variation of the relative amount of light under such control. Contrarily to the previous example in the case where the light source is driven by a constant current, the amount of light starts increasing immediately after the light source is lighted and gradually approaches a certain value. This control also takes time until the amount of light reaches the certain value and becomes stable. For delicate measurement in laboratories, the light source is driven to stabilize the output and then lighted continuously for thirty minutes to one hour before the measurement is started.

Waiting for the stabilization of output of the light source delays the time to start measurement and wastes power not to contribute to the measurement. This power consumption could be a big issue particularly in the case where the measurement apparatus has a limitation in the power source, like a portable device. Described in the following is a method of acquiring a desirable output value from data measured under a positive magnetic field and a negative magnetic field even in the condition where the amount of light from the light source is gently varying.

The magneto-optical measurement described in the following measures the amount of light reflected by a thin-film sensor for a plurality of times under each of a positive magnetic field and a negative magnetic field. The magneto-optical measurement determines one or more regression formulae and determines a specific output value based on the one or more regression formulae. As a result, a more accurate output value can be obtained from the amounts of light reflected under the positive and the negative magnetic fields.

### Device Configuration

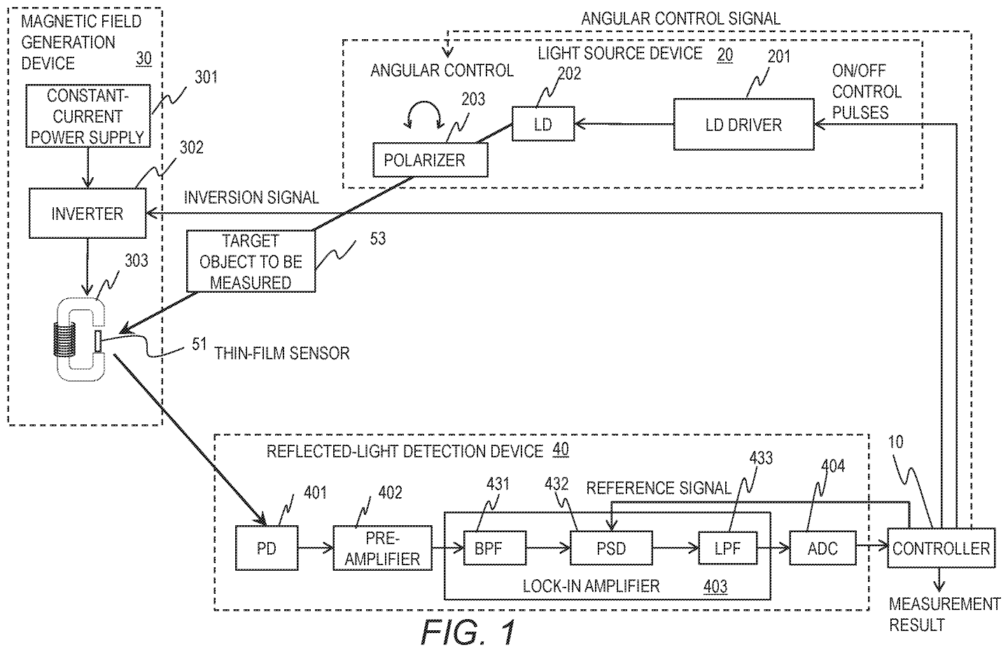

FIG. 1 schematically illustrates a configuration example of a magneto-optical measurement apparatus. Although a polarimeter is described in the following by way of example of a magneto-optical measurement apparatus, the features of this disclosure are applicable to various kinds of magneto-optical measurement apparatuses.

With reference to FIG. 1, the magneto-optical measurement apparatus includes a controller 10, a light source device 20, a magnetic field generation device 30, and a reflected-light detection device 40. A thin-film sensor 51 is mounted on the magnetic field generation device 30. The controller 10 controls the devices in the magneto-optical measurement apparatus, measures the amount of light reflected by the thin-film sensor 51, and calculates a measurement value based on the amounts of the reflected light.

The light source device 20 generates light to be received by the thin-film sensor 51. The light source device 20 includes an LD driver 201, an LD 202, and a polarizer 203. The LD driver 201 supplies the LD 202 with driving current in accordance with the control of the controller 10. The LD 202 generates and emits light to be received by the thin-film sensor 51. The LD 202 is an example of a light source and can be replaced by a light-emitting diode, for example. The light from the LD 202 includes a specific wavelength suitable for measurement with the thin-film sensor 51; it can be monochromatic light having the specific wavelength.

The controller 10 controls the LD driver 201 to supply pulse-modulated driving current to the LD 202. The LD 202 is controlled to be ON/OFF in accordance with the driving current. In other words, the LD 202 blinks in predetermined cycles. The frequency of the blinking of the LD 202 can be approximately 520 Hz. Instead of the pulse-modulated current, a mechanical optical chopper can be used to modulate the light from the LD 202.

The polarizer 203 selectively transmits light oscillating in a specific direction (linearly polarized light) out of the received light and attenuates the light oscillating in the other directions. In other words, the polarizer 203 generates light polarized linearly at a predetermined angle from the light from the LD 202. The polarization angle of the polarizer 203 is adjusted so that the plane of polarization of the linearly polarized light will have a predetermined angle with the target object 53 to be measured. Although this configuration example uses the LD 202 and the polarizer 203 to generate linearly polarized light, another configuration example can exclude the polarizer 203 by employing a light source device that outputs linearly polarized light, such as a semiconductor laser with a built-in polarizer.

The magnetic field generation device 30 generates a magnetic field to be applied to the thin-film sensor 51. The magnetic field generation device 30 includes a constant-current power supply 301, an inverter 302, and a magnetic field generator 303. The magnetic field generator 303 includes a magnetic yoke wound with a coil. The thin-film sensor 51 is disposed within a magnetic gap of the magnetic yoke. The controller 10 controls the constant-current power supply 301 to supply excitation current enough to saturate the magnetization of the magnetic film (magnetic metal layer) of the thin-film sensor 51 to the coil of the magnetic field generator 303 via the inverter 302.

In the example described in the following, the magnetic field generator 303 alternately applies magnetic fields (+H, −H) having the equal intensity enough to saturate the magnetization of the magnetic film but having opposite directions. The magnetization of the magnetic film does not need to be saturated if the positive magnetic field and the negative magnetic field have opposite directions and equal magnitude. However, as far as the size of the magnetic field generation mechanism is finite, the generated magnetic field has different intensities between the inside and the periphery of the mechanism. For this reason, to uniformize the intensity of a magnetic field, the magnetic field generation mechanism needs to be large, which is not practically useful in the points of the size, the weight, and the driving power. Applying a magnetic field that saturates the magnetization of the magnetic film enables any points of the whole magnetic film to be fully magnetized, so that the uniformity and the stability of the magnitude of the magnetization are achieved in both the positive and the negative magnetization.

The controller 10 controls the inverter 302 to cyclically invert the current from the constant-current power supply 301 and supplies the current to the magnetic field generator 303. As a result, repeatedly reversing positive and negative magnetic fields can be generated. The reversal cycle of the magnetic field can be several seconds. The inverter 302 is an electric circuit for inverting the current from the constant-current power supply and can be an H-bridge.

Combining a inverter with a constant-current power supply as described above enables the coil to receive a constant current and further, enables the positive excitation current and the negative excitation current to have the same magnitude, even if the inverting circuit shows slightly different characteristics (such as internal resistance) after switching the positive mode and the negative mode. In other words, applying magnetic fields that are different only in the direction of excitation current but the same in intensity causes magnetization different only in the direction (positive or negative) but of the same magnitude in the thin-film sensor 51, so that highly accurate measurement becomes available.

The reflected-light detection device 40 detects light reflected by the thin-film sensor 51. The magneto-optical effect of the thin-film sensor 51 appears in multiple modes, which are determined depending on the direction of the magnetic field with respect to the thin-film sensor 51 and the incident light. Specifically, there are polar Kerr effect, longitudinal Kerr effect, and transversal Kerr effect.

The polar Kerr effect occurs when the magnetization of the magnetic film of the thin-film sensor 51 is perpendicular to the reflection surface. The longitudinal Kerr effect occurs when the magnetization is parallel to the reflection surface and also parallel to the plane of incidence. The transversal Kerr effect occurs when the magnetization is parallel to the reflection surface and perpendicular to the plane of incidence.

The change in characteristic of the reflected light because of the polar Kerr effect or the longitudinal Kerr effect appears as change in polarization angle. The change in characteristic of the reflected light because of the transversal Kerr effect appears as change in the amount of the reflected light. For a reflected-light detection device, the configuration to measure the amount of light is available easily and therefore, an example of measuring the amount of light under the transversal Kerr effect is described in the following. Under the polar Kerr effect or the longitudinal Kerr effect, the change in polarization angle of the reflected light from the thin-film sensor 51 can be converted to the change in the amount of light by transmitting the light reflected by the thin-film sensor 51 through a polarizer.

As illustrated in FIG. 1, the reflected-light detection device 40 includes a photodetector (PD) 401, a pre-amplifier 402, a lock-in amplifier 403, and an A/D converter (ADC) 404. The pre-amplifier 402 amplifies a detection signal from the PD 401 to a level suitable for the lock-in amplifier 403 to process.

The lock-in amplifier 403 detects a low signal in noise with high sensitivity. The lock-in amplifier 403 includes a band-pass filter (BPF) 431, a phase-sensitive detector (PSD) 432, and a low-pass filter (LPF) 433. As described above, the light from the LD 202 is AC-pulse modulated. The detection signal of the PD 401 corresponds to the light emitted from the LD 202 and changed by the Kerr effect at the thin-film sensor 51; it is a signal having the same frequency and the same phase as the modulated signal from the light source device 20 and various noise components are superimposed on this signal. The BPF 431 selectively transmits the modulation frequency component and attenuates the other components. As a result, most of the noise components having the other frequencies are removed. The BPF 431 can be replaced by a tuning amplifier.

The PSD 432 rectifies the signal from the BPF 431 in synchronization with the modulated signal from the light source device 20 to remove the components different from the modulation signal in phase. Specifically, the PSD 432 receives a reference signal (rectangular wave with a duty of 50%) having the same frequency as the modulated signal and adjusted in phase by the amount shifted before reaching the PSD 432. The PSD 432 switches inversion and non-inversion of the signal from the BPF 431 based on the reference signal to achieve full-wave rectification. Through this operation, the components different from the modulated signal in phase are removed.

The LPF 433 extracts the DC component from the signal received from the PSD 432 to generate the final measurement signal. As understood from the above, the lock-in amplifier 403 can extract the component having the same frequency and the same phase as the modulated blinking signal of the LD 202 with high sensitivity. Note that this synchronized measurement with the lock-in amplifier is optional.

The method for a magneto-optical measurement apparatus to measure the optical rotation of a target object is described. As described above, light linearly polarized at a specific polarization angle and modulated to blink is emitted from the light source device 20 and passes through a target object 53. The polarization angle of the linearly polarized light changes in accordance with the optical rotation of the object 53 as the light passes through the object 53. An example of the object 53 is a liquid contained in a transparent container.

The light from the LD 202 transmitted through the object 53 enters the thin-film sensor 51 and is reflected by the thin-film sensor 51. Under a positive magnetic field (+H) or a negative magnetic field (−H), the amount of the light reflected by the thin-film sensor 51 depends on the polarization angle of the incident light. The amount of the reflected light is converted by the PD 401 into an electric signal and the electric signal is amplified by the pre-amplifier 402.

The lock-in amplifier 403 extracts and outputs the signal of the light emitted from the LD 202 and reflected by the thin-film sensor 51 in synchronization with the modulation frequency of the LD 202. The output from the lock-in amplifier 403 is converted by the ADC 404 into a digital signal and input to the controller 10. The modulation frequency of the LD 202 is sufficiently higher than the frequency of switching magnetic fields

The controller 10 calculates the amounts of reflected light in the positive magnetic field and the negative magnetic field as of the same time based on the values obtained by measuring the amount of reflected light under a positive magnetic field and a negative magnetic field for a plurality of times. The controller 10 determines the value (Kerr output value) representing the degree of optical rotation of the target object 53 from the calculated amounts of reflected light in the positive magnetic field and the negative magnetic field as of the same time. The details of the processing of the controller 10 will be described later.

### Configuration of Thin-Film Sensor

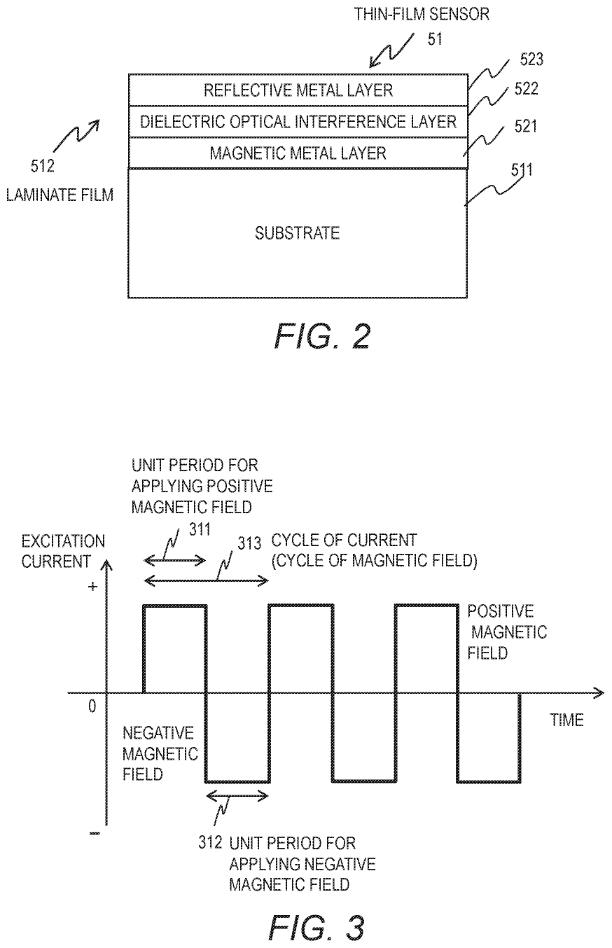

FIG. 2 illustrates an example of a laminate structure of the thin-film sensor 51. A laminate film 512 is provided on a substrate 511. The thin-film sensor 51 is illuminated with linearly polarized light under the condition that the magneto-optical effect is enhanced because of multiple reflection within the laminate film 512. The substrate 511 can be a glass substrate having a thickness of approximately 0.5 mm (500 μm). The laminate film 512 is formed by stacking a magnetic metal layer 521, a dielectric optical interference layer 522, and a reflective metal layer 523 in this order from the bottom to the top. The thicknesses of the individual layers are determined appropriately so that the light that has entered the laminate film 512 will be multiply reflected within the laminate film 512. For example, the thicknesses of the magnetic metal layer 521 and the dielectric optical interference layer 522 are approximately 100 nm and the thickness of the reflective metal layer 523 is approximately 10 nm.

The magnetic metal layer 521 can be a monolayer film or a multilayer film of common magnetic material such as a metal of Fe, Co, or Ni or an alloy thereof. For example, a soft magnetic material that exhibits large magneto-optical effect and gets saturated in a low magnetic field, such as an FeCo alloy or an FeSi alloy, can be used. The dielectric optical interference layer 522 can be made of an oxide or a nitride that is transparent for a specific wavelength of light, such as SiO₂, ZnO, MgO, TiO₂, or AlN. The material for the reflective metal layer 523 can be a common metallic material such as Ag, Al, Au, Cu or an alloy thereof having high reflectance to the specific wavelength of light emitted from the LD 202.

The laminate film 512 can have a configuration different from the configuration in FIG. 2. For example, the laminate film 512 can be formed by stacking the films on the substrate 511 in the order of the reflective metal layer 523, the dielectric optical interference layer 522, and the magnetic metal layer 521. In the case where the magneto-optical measurement apparatus is designed to detect a gas, the laminate film further includes a gas sensing layer that changes in optical characteristics in response to contact with the gas.

### Generation of Magnetic Field

Change of the amount of light reflected by the laminate film 512 is described. FIG. 3 schematically illustrates an example of temporal variation of the excitation current in the magnetic field generation device 30. The excitation current changes its direction between a positive direction and a negative direction in a cycle 313. The positive excitation current generates a positive magnetic field and the negative excitation current generates a negative magnetic field.

The positive excitation current and the negative excitation current are at the same value; the positive magnetic field and the negative magnetic field generated thereby have the same intensity enough to saturate the magnetization of the whole magnetic metal layer 521. The positive magnetic field and the negative magnetic field saturate the magnetization of the magnetic metal layer 521 in the opposite directions. The unit period for supplying the positive excitation current (unit period for applying a positive magnetic field) 311 and the unit period for supplying the negative excitation current (unit period for applying a negative magnetic field) 312 have the same length. The positive and the negative magnetization of the magnetic metal layer 521 need to have opposite directions and the same magnitude. In view of the distribution of the magnetic field generated by the magnetic field generator, the magnitudes of the positive and the negative magnetization can be equalized easily by applying magnetic fields that saturate the magnetization of the magnetic film.

As described above, the magnetic field the magnetic field generation device 30 applies to the laminate film 512 for measurement of the amount of the reflected light changed by the transversal Kerr effect is parallel to the magnetic metal film 521 and perpendicular to the plane of incidence.

A magnetic film has magnetic anisotropy (an easy axis and a hard axis). Its magnetization curve shows difference depending on the direction of application of a magnetic field. When a magnetic field is applied in the direction along the easy axis, the magnetization is reversed with a large amplitude to be saturated under a comparatively low magnetic field. In contrast, when a magnetic field is applied in the direction along the hard axis, the magnetization changes gently in accordance with the intensity of the magnetic field and is eventually saturated under a comparatively high magnetic field. This embodiment uses a saturated magnetic film, as described above and accordingly, a configuration that applies a magnetic field along the easy axis to attain saturated magnetization with a low magnetic field is preferable because the electric power to generate the magnetic field can be saved.

As to the material for the magnetic film, there are materials that tend to have an easy axis in parallel to the film surface and materials that tend to have an easy axis perpendicularly to the film surface. The magnetization of the materials having a parallel easy axis can be reversed and saturated under a magnetic field lower by a single digit or double digits than the magnetization of the materials having a perpendicular easy axis. Accordingly, the materials that tend to have an easy axis in parallel to the film surface can save the electric power for the magnetization. Among the aforementioned three modes of Kerr effect, what appears in magnetization parallel to the film surface are the transversal Kerr effect and the longitudinal Kerr effect.

The thin-film sensor 51 including the magnetic metal layer 521 is disposed in the magnetic gap of the magnetic yoke, as described above. The magneto-optical measurement apparatus in this disclosure illuminates a fully magnetized or saturated magnetic metal layer 521 with light and measures the amount of acquired reflected light. In disposing the thin-film sensor in a space (gap) of the magnetic yoke to apply a magnetic field, it is preferable to dispose the sensor film close to the center of the gap, considering the magnetic field distribution within the gap. When the gap is seen from the side of the incident light and the reflected light, the center of the gap is located deep in the gap. In the layout to acquire the longitudinal Kerr effect, the optical path for supplying light to the thin-film sensor 51 and acquiring reflected light therefrom is positioned to graze the edge of the magnetic yoke. However, in the layout to acquire the transversal Kerr effect, the optical path is positioned in the magnetic gap where the magnetic yoke does not exist. Accordingly, the measurement method utilizing the transversal Kerr effect is easier to design the measurement apparatus because the optical path is positioned within the gap and is not intercepted by the magnetic yoke. This is the reason why the magneto-optical measurement apparatus in this disclosure employs the measurement method utilizing the transversal Kerr effect.

Linearly polarized light enters the laminate film 512 under the condition that a positive or a negative magnetic field to saturate the magnetization of the magnetic metal layer 521 is being applied. The linearly polarized light is multiply reflected within the laminate film 512 and receives magneto-optical effect. The amount of light emitted from (reflected by) the laminate film 512 changes from the amount R when the magnetic metal layer 521 is zero-magnetized by +ΔR or −ΔR.

The variation ±ΔR in the amount of reflected light under the positive or negative saturated magnetization is different depending on the polarization angle of the incident light. This is because the optical interference condition of the laminate film 512 changes with the polarization angle of the incident light and differently affects the multiple reflection. Accordingly, the degree of optical rotation of the target object 53 can be determined based on the measured amount of the light reflected by the thin-film sensor 51.

The controller 10 can provide a function so-called calibration that measures the relation between the degree of optical rotation (the polarization angle of the light incident on the thin-film sensor) and the Kerr output value to the magneto-optical measurement apparatus. The operation of this function is as follows. The controller 10 rotates the polarizer 203 to change the polarization angle of the incident light. The controller 10 illuminates the thin-film sensor 51 with pulse-modulated linearly polarized light while applying cyclically alternating positive magnetic field and negative magnetic field to the thin-film sensor 51 and calculates the Kerr output value (magneto-optical output value) from the amounts of reflected light measured under the positive magnetic field and the negative magnetic field. The relation between the polarization angle and the Kerr output value can be obtained by repeatedly changing the polarization angle and measuring the amount of reflected light. The controller 10 determines and stores the relation between the polarization angle and the Kerr output value.

This calibration function can be executed by an external control mechanism with a rotation control mechanism for the polarizer to fix the polarizer 203 at a specific angle in manufacturing and tuning the measurement apparatus. Then, the mechanism to control the polarization angle of the polarizer 203 with the controller 10 can be eliminated from the measurement apparatus to lower the price of the measurement apparatus.

To measure the degree of optical rotation, the operator sets the polarizer 203 at an angle where the measured amount of reflected light will be the middle between the maximum value and the minimum value and then sets the target object 53. The controller 10 measures the intensity of light transmitted through the target object 53 and reflected by the thin-film sensor 51 under the alternating positive magnetic field and negative magnetic field to determine the Kerr output value. The degree of optical rotation of the target object 53 can be determined by comparing the Kerr output value with the aforementioned predetermined relation. Setting the polarizer 203 at the angle where the measured amount of reflected light will be the middle between the maximum value and the minimum value enables measurement of the optical rotation of the target object 53, no matter whether the optical rotation is dextrorotary or levorotary.

### Relation Between Magnetic Field and Amount of Reflected Light

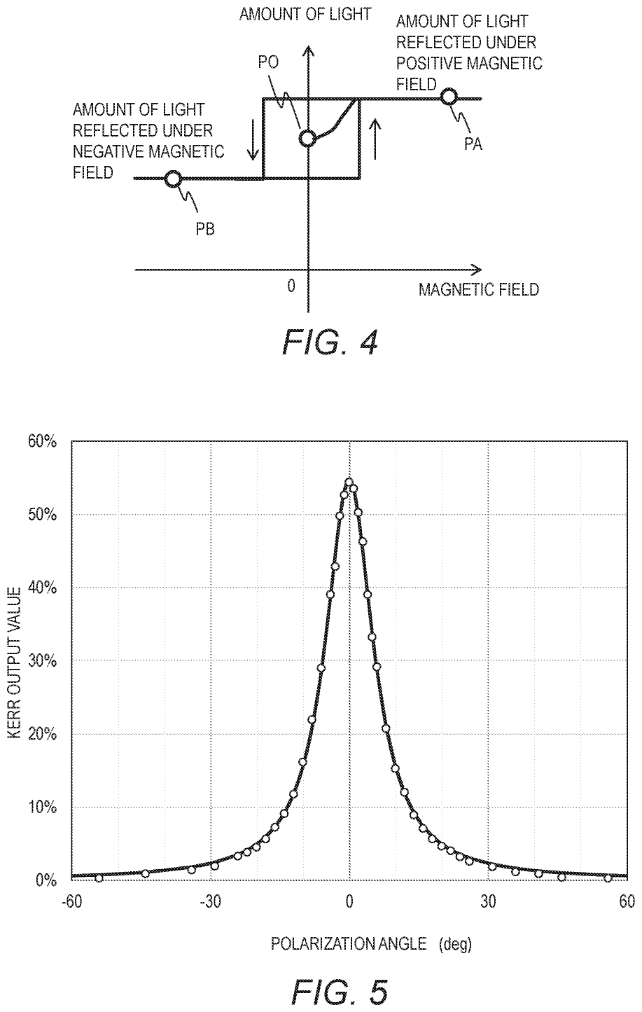

FIG. 4 schematically illustrates a relation between the alternating magnetic fields and the amount of reflected light. FIG. 4 provides a loop plotted with a principled virtual line. The part rising from the point PO virtually represents the variation corresponding to the initial magnetization curve from the zero magnetization. The controller 10 acquires measured amounts of reflected light only at the point PA and the point PB. The magnetization of the thin-film sensor 51 is saturated at the point PA and the point PB.

Let the amounts of reflected light at the point PO under zero magnetization (zero magnetic field), at the point PA under a positive magnetic field, and at the point PB under a negative magnetic field be O, A, and B, respectively. The measurement result (Kerr output value) X to be obtained can be expressed as X=(A−B)/O and it is a dimensionless quantity. Accordingly, the absolute values of the amounts of reflected light do not affect the measurement result. The variation in the amount of reflected light under the positive magnetic field (positive magnetization) and the variation in the amount of reflected light under the negative magnetic field (negative magnetization) are symmetric about the zero magnetization.

Let the differences of the amounts of reflected light at the point PA and the point PB from the amount of reflected light at the zero magnetization be ΔR. The amount A of the reflected light at the point PA is O+ΔR; the amount B of the reflected light at the point PB is O−ΔR; and the amount O of the reflected light at the point PO is (A+B)/2. As understood from these relations, the Kerr output value can be calculated if any two of these values of O, A, and B are found. However, a magnetic material generally has residual magnetization and therefore, attaining a zero-magnetization state in actual measurement is perplexing because demagnetization process is necessary. Accordingly, it is more realistic to obtain the Kerr output value X from the two amounts A and B of the reflected light. Specifically, the Kerr output value X can be obtained by (A−B)/((A+B)/2).

### Relation Between Kerr Output Value and Polarization Angle

As described above, the controller 10 calculates the degree of optical rotation of the target object 53 from the Kerr output value X. FIG. 5 illustrates an example of the relation between the Kerr output value obtained as described above and the polarization angle of incident light. The Kerr output value sharply changes with polarization angle. As described above, this relation is measured in advance. The controller 10 holds information such as a look-up table or a function that indicates the relation between the Kerr output value and the polarization angle.

The controller 10 uses this relation to determine the polarization angle of the incident light on the thin-film sensor 51 from the Kerr output value of the target object 53. The controller 10 maintains the light from the light source device 20 at a fixed polarization angle during the measurement on the target object 53 to obtain the degree of optical rotation of the target object 53 from the distance the light passes through the target object 53 placed on the optical path to the thin-film sensor 51 and the polarization angle of the detected reflected light.

Since the external magnetic field applied to the thin-film sensor 51 changes with time, the time of reflected light measurement at the point PA and the time of reflected light measurement at the point PB are different. To obtain an accurate Kerr output value, it is important that the intensity of light is the same at the point PA and the point PB. However, it takes a certain time until the output of the light source is stabilized at a constant value, as described above. If the measurement is postponed until the output of the light source becomes stable, it takes time to start the measurement and electric power not compensating for measurement is wasted during the period for the stabilization.

The controller 10 calculates the amounts of reflected light under a positive magnetic field and a negative magnetic field as of the same given time from the amounts of reflected light measured under the positive magnetic field and the negative magnetic field during the period where the amount of light from the light source is gently changing. Hence, speedy measurement and low power consumption become available. Hereinafter, the process of measurement by the controller 10 is described.

### Values Measured and Valid Data

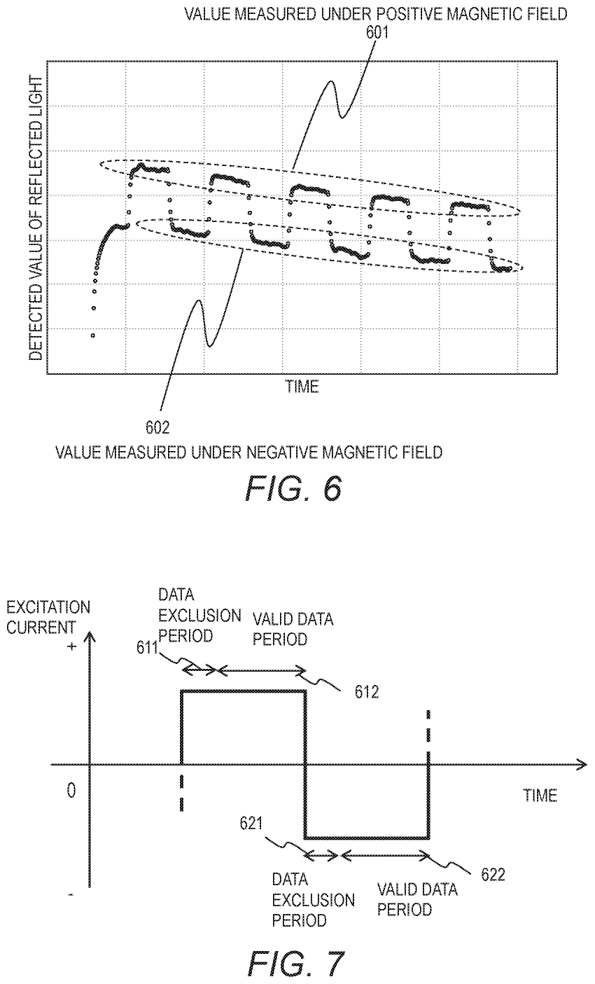

FIG. 6 provides an example of the output of the lock-in amplifier 403 converted by the ADC 404 into a digital signal. The output signal (detected signal) has a rectangular waveform in accordance with alternation of magnetic fields. The high-level output values 601 in the rectangular waves are output values under the positive magnetic field and the low-level output values 602 in the rectangular waves are output values under the negative magnetic field. In each period under the positive magnetic field and the negative magnetic field, a plurality of detected amounts of light are output.

The output signal gradually falls as the output of the light source gradually falls. The controller 10 maintains the optical path at the same position and the excitation current of the magnetic field generation device 30 for generating an external magnetic field at a constant value but alternates only the direction of the excitation current. This control minimizes the variable factors in the measurement conditions other than the output of the light source.

As described above, the amount of light reflected under a positive magnetic field and the amount of light reflected under a negative magnetic field cannot be measured simultaneously. Further, the amounts of reflected light measured under a positive magnetic field are not constant, and the amounts of reflected light measured under a negative magnetic field are not constant, either, chiefly because of the variation in output of the light source. For these reasons, the controller 10 determines a regression formula (first regression formula) for the values measured under a positive magnetic field and a regression formula (second regression formula) for the values measured under a negative magnetic field to calculate the value expected to be measured under a positive magnetic field and the value expected to be measured under a negative magnetic field at the same given time with those regression formulae.

In an example, the controller 10 selects a part of the measured values to calculate a more accurate regression formula. Specifically, in switching a positive magnetic field and a negative magnetic field, there is a transition period until stable values are acquired. The transition period is a period until the reversal of the magnetic field is completed and the variations of the measured values caused by the reversal of the magnetic field are stabilized in the output of the lock-in amplifier 403.

FIG. 7 illustrates measurement periods to be excluded and measurement periods to be used for the controller 10 to calculate the regression formulae. A data exclusion period 611 is defined immediately after negative excitation current (or zero excitation current) is reversed to positive excitation current; a valid data period 612 is defined subsequently to the data exclusion period 611. Further, a data exclusion period 621 is defined immediately after positive excitation current (or zero excitation current) is reversed to negative excitation current; a valid data period 622 is defined subsequently to the data exclusion period 621. The controller 10 selects the measured values in the valid data periods 612 and 622 and uses them to calculate the regression formulae.

The lock-in amplifier 403 includes an LPF 433 at the final stage as understood from the configuration in FIG. 1. The lock-in amplifier 403 has a delay time or a time constant determined by the circuit constants until a possible change in the signal input to the pre-amplifier 402 appears in the output of the LPF 433. In addition, the magnetic field generator 303 as an element of an electric circuit is a coil (inductance); there is a delay after the applied voltage is switched until the current is stabilized at a constant value. Since a magnetic field is generated by the current, the magnetic field has a transition period until the intensity of the magnetic field applied to the thin-film sensor 51 is stabilized at a constant value. Accordingly, the reversal cycle of the magnetic field is determined to be able to perform measurement for a sufficient number of times in view of both the transition period of the magnetic field (data exclusion period) and the time constant of the lock-in amplifier 403.

### Regression Formulae

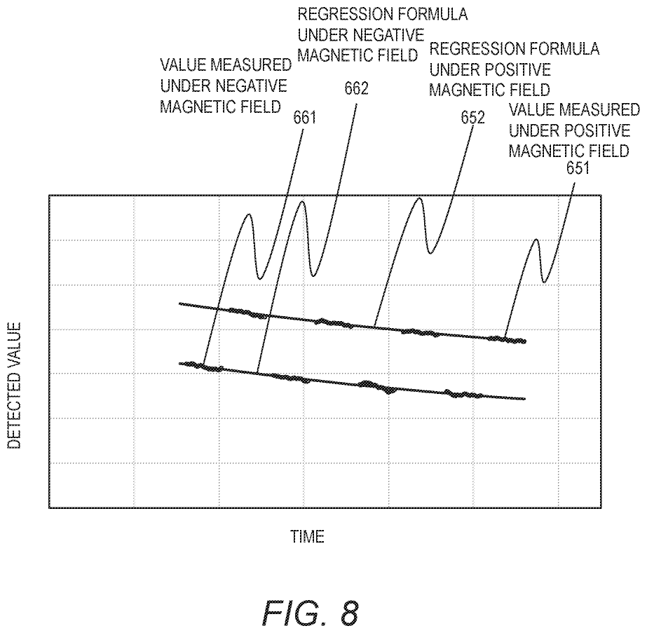

FIG. 8 illustrates examples of relations between valid measured values and regression curves plotted in accordance with regression formulae. In this section, a regression curve plotted in accordance with a regression formula shown in a drawing is referred to as regression formula to avoid complexity of the description. The controller 10 calculates a regression formula 652 from a plurality of valid values 651 measured under a positive magnetic field. In similar, the controller 10 calculates a regression formula 662 from a plurality of valid values 661 measured under a negative magnetic field. For example, the controller 10 calculates the regression formula 652 from a plurality of values 651 measured in a plurality of unit periods for applying a positive magnetic field. In similar, the controller 10 calculates the regression formula 662 from a plurality of values 661 measured in a plurality of unit periods for applying a negative magnetic field.

In FIG. 8, each of the regression formulae 652 and 662 is a quadratic function. In calculating the regression formula 652 in a positive magnetic field, the controller 10 does not use the values measured in the periods of negative magnetic field. In similar, in calculating the regression formula 662 in a negative magnetic field, the controller 10 does not use the values measured in the periods of positive magnetic field. However, the variation in output of the light source has no relation with the variation in magnetic field and therefore, if the magnetic field is constant, the measured values should have a pattern depending on only the variation in output of the light source. Accordingly, an appropriate regression formula can be obtained from values measured intermittently.

The temporal variation of the output of the light source is simple and accordingly, it can be expressed by a linear function if the time is short, or a quadratic function in view of the principle that the output varies with a curvature. For efficient arithmetic operation and acquisition of an appropriate regression formula, a quadratic formula is preferable. Other functions can be used, such as exponential functions, logarithmic functions, and even more complicated functions that precisely describe the physical phenomenon of the variation in output of the light source, if it is applicable.

The controller 10 calculates the amounts of light (expected to be measured) A and B under a positive magnetic field and a negative magnetic field as of the same given time using the regression formula 652 in a positive magnetic field and the regression formula 662 in a negative magnetic field. The controller 10 calculates the Kerr output value as of the same given time from the calculated amounts of light A and B.

In an example, the controller 10 determines the Kerr output value using the calculated values as of a time within a range where measurement results exist. This configuration achieves higher accuracy than the configuration using the calculated values as of a time outside any range where measurement results exist. Alternatively, the controller 10 can calculate values as of a plurality of times and use the average of the Kerr output values obtained from those values as the Kerr output value to be obtained. This configuration increases the accuracy in acquisition of the Kerr output value.

In the example of FIG. 8, the controller 10 determines a regression formula 652 in a positive magnetic field from the values 651 actually measured under the positive magnetic field and determines a regression formula 662 in a negative magnetic field from the values 661 actually measured under the negative magnetic field. In another example, the controller 10 determines a regression formula (third regression formula) in zero magnetization from the values measured under a positive magnetic field and the values measured under a negative magnetic field and determines the Kerr output value based on the regression formula.

The variation of reflected light caused by variation of the output of the light source can be measured even under zero magnetization. The Kerr effect caused by an external magnetic field is added to this variation of the reflected light to be the value measured in a positive or negative magnetic field. The actual measurement data includes the variation caused by variation of the output of the light source. This example is based on this theory and determines the regression formula for the values to be measured under zero magnetization.

In the case where regression formulae are obtained from the values measured under a positive magnetic field and the values measured under a negative magnetic field, there is no relation to connect these regression formulae. If only either the positive magnetic field or the negative magnetic field has some unique noise component, the regression formula based thereon is affected to impair the accuracy in measurement. A model that determines the amount of light under the positive magnetic field and the amount of light under the negative magnetic field with one regression formula representing the gentle variation of the amount of light more appropriately accords to the physical phenomenon; the relation between the positive magnetic field and the negative magnetic field will be less affected by the noise component accidentally. For this reason, this method enables more accurate measurement.

The value measured under no external magnetic field should be the middle value between the values simultaneously measured in a positive magnetic field and a negative magnetic field, if such measurement is possible. The Kerr output value is constant even if the output of the light source varies, as far as the conditions other than the output of the light source are unchanged. Accordingly, if the Kerr output value is known, the regression formula of the amounts of light measured under zero magnetization can be obtained.

A specific process is described. In an example, the controller 10 calculates an average VA of valid values measured under a positive magnetic field and further, calculates an average VB of valid values measured under a negative magnetic field. The controller 10 calculates a temporary Kerr output value VX from the averages VA and VB. Specifically, the temporary Kerr output value VX is calculated by (VA−VB)/((VA+VB)/2). The temporary value VX is not accurate enough to be employed as a measured value but the true Kerr output value X should be close to this value.

The controller 10 calculates back the values expected to be measured under zero magnetization based on the values measured under the positive magnetic field in the periods of positive magnetic field and the temporary Kerr output value VX. Further, the controller 10 calculates back the values expected to be measured under zero magnetization based on the values measured under the negative magnetic field in the periods of negative magnetic field and the temporary Kerr output value VX.

The controller 10 calculates a regression formula from the obtained values to be measured in zero magnetization and calculates the residual sum of squares. The controller 10 searches for the Kerr output value with which the residual sum of square takes the smallest value. The detected Kerr output value is the appropriate Kerr output value to be obtained.

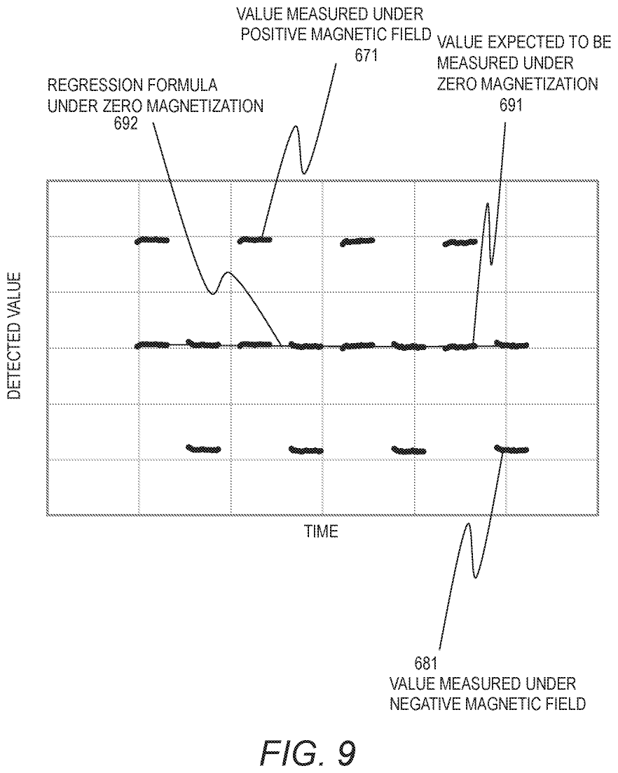

FIG. 9 illustrates an example of values 671 actually measured under a positive magnetic field, values 681 actually measured under a negative magnetic field, values 691 expected to be measured under zero magnetization that are calculated based on the appropriate Kerr output value obtained by the foregoing method, and the regression formula 692 therefor. In this example, one regression formula 692 expresses gentle variation of the amount of light from the light source and a certain level of Kerr effect acts on the regression formula 692 to become the actually measured values. Hence, this is a method more conforming to the physical model to process the measured data.

Next, a method of reducing the initial large variation of the output of the light source when the light source is lighted is described. As described above, the output of a light source such as an LD or an LED varies significantly in several tens of seconds after the light source is lighted. Even if the measurement method allows for gentle output variation, reducing this large variation enables more accurate measurement.

### Control of Light Source

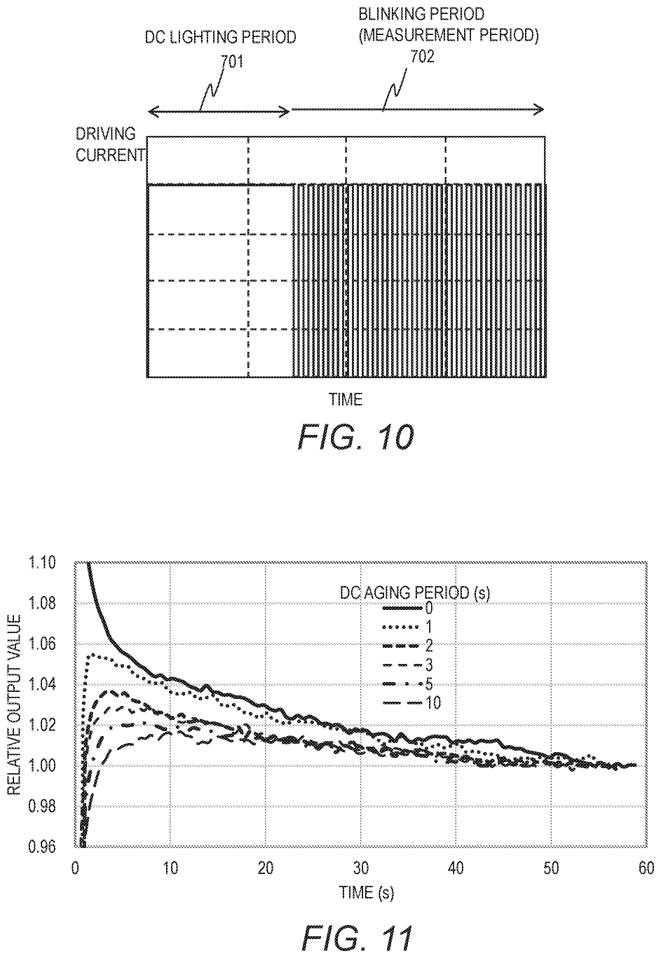

FIG. 10 illustrates an example of temporal variation of the driving current for the light source. In a DC lighting period 701 that begins when the light source is lighted, a constant direct current is supplied to the light source. A blinking period (measurement period) 702 follows the DC lighting period 701. In the blinking period 702, the aforementioned alternating pulse-modulated current is supplied to the light source. The controller 10 controls the inverter 302 to invert the DC current from the constant current power supply 301 and supplies an alternating rectangular wave current to the magnetic field generator 303.

The controller 10 measures the amount of light reflected by the thin-film sensor 51 within the blinking period 702. In this way, the controller 10 lights the light source with a constant direct current before starting blinking the light source for measurement. The lighting with the DC current is switched to the blinking instantly without an interval. This control enables reduction in the initial variation of the output of the light source when the light source is lighted. In other words, the light source can be used in such a manner that the light source is turned on only when starting measurement.

FIG. 11 provides comparison results of output of the light source in the cases where the light source rested for a sufficiently long time is turned on and provided with different DC lighting (aging) periods between 0 seconds and 10 seconds before being switched to the pulsed constant current driving (at a duty of 50%). FIG. 11 does not show the output values during the aging periods. The tendency of the output falling immediately after lighting, which is unique to the constant-current driving, is moderated as the DC aging period becomes longer. Since the degree of this effect varies with the characteristics of the light source element and the driving current, the DC aging period is to be adjusted to attain desired characteristics depending on the element and the driving current. Instead of DC lighting, the same effect of aging can be attained by making the pulses have a larger duty than the pulses in the measurement period.

In the above-described configuration, the controller 10 alternately applies magnetic fields having the same intensity and opposite directions to the thin-film sensor 51. The magnetic fields have an intensity enough to saturate the magnetization of the magnetic metal layer 521 of the thin-film sensor 51. The magnetization state of the magnetic metal layer 521 required for measurement is only the saturated state in both the positive and the negative directions. Intermediate magnetization states are not necessary and therefore, operation to gradually change the intensity of the applied magnetic field is unnecessary. For this reason, the controller 10 performs operation to reverse and apply the magnetic field of an intensity enough to saturate the magnetization of the magnetic metal layer 521.

The controller 10 blinks the LD 202 to perform synchronized measurement (lock-in measurement) of the amount of the light reflected by the thin-film sensor 51. The cycle of reversal of the magnetic field is sufficiently longer than the cycle of blink of the LD 202. The controller 10 reads the amount of reflected light with intervals sufficiently shorter than the cycle of reversal of the magnetic field. In other words, in each period where a positive magnetic field or a negative magnetic field is maintained at a specific intensity, the controller 10 acquires values measured at a plurality of times.

The controller 10 does not include the values measured in the transition periods of the reversal of the magnetic field and the following periods until the output of the lock-in amplifier 403 is stabilized in valid values. The frequency of reversal of the magnetic field and the frequency of modulation of the light are determined so that stable output can be obtained from the lock-in amplifier 403 during the period where the magnetic field is stable, whichever it is a positive magnetic field or a negative magnetic field. The controller 10 repeats the reversal of the magnetic field for a plurality of times and repeatedly acquires a measured value in the period where the magnetic field and the output of the lock-in amplifier are stable.

The controller 10 determines a regression formula in zero magnetization or regression formulae in a positive magnetic field and a negative magnetic field from the valid amounts of reflected light measured under a positive magnetic field and a negative magnetic field. The controller 10 determines a Kerr output value with the regression formula in zero magnetization or the regression formulae in a positive magnetic field and a negative magnetic field.

As described above, under the conditions that the output of the light source is gently changing and that the simultaneous measurement in the positive magnetic field and the negative magnetic field is impossible, this embodiment can obtain the values expected to be measured in a positive magnetic field and a negative magnetic field at the same time when the output of the light source is the same and therefore, the Kerr output value can be obtained based on the calculated values.

Employment of synchronized measurement with a lock-in amplifier increases the S/N ratio and attains practically sufficient measurement accuracy without an optical bandpass filter. Since the synchronized measurement is performed with a light source blinking, the power consumption is lowered by the amount corresponding to the unlighted periods in the blinking, compared to DC lighting.

This embodiment does not need to stabilize the output of the light source by lighting the light source for a long time. The waiting time until measurement is reduced to save the power consumption and therefore, this feature is particularly effective to portable devices to operate with a battery. Since the embodiment requires a shorter lighting period, degradation in performance of the light source can be delayed to provide the apparatus with a long lifespan. The magnetic film in the sensing element is supplied with only a positive and a negative magnetic fields of the intensity to saturate its magnetization and not supplied with intermediate magnetic fields and therefore, the measurement can be expedited and the power consumption can be saved.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A magneto-optical measurement apparatus comprising:
a light source;
a thin-film sensor including a magnetic film and being configured to reflect light from the light source;
a magnetic field generation device configured to apply a magnetic field to the thin-film sensor; and
a controller,
wherein the magnetic field generation device is configured to alternately supply a positive magnetic field and a negative magnetic field to the thin-film sensor to alternately cause positive magnetization and negative magnetization having equal magnitude but opposite directions in the magnetic film, and
wherein the controller is configured to:
measure the amount of light reflected by the thin-film sensor at a plurality of times under the positive magnetic field;
measure the amount of light reflected by the thin-film sensor at a plurality of times under the negative magnetic field;
determine one or more regression formulae from the values measured under the positive magnetic field at the plurality of times and the values measured under the negative magnetic field at the plurality of times; and
determine a specific output value based on the one or more regression formulae.

2. The magneto-optical measurement apparatus according to claim 1, wherein each of the positive magnetic field and the negative magnetic field saturates magnetization of the magnetic film.

3. The magneto-optical measurement apparatus according to claim 1,
wherein the plurality of times under the positive magnetic field include times in a plurality of unit periods for applying the positive magnetic field, and
wherein the plurality of times under the negative magnetic field include times in a plurality of unit periods for applying the negative magnetic field.

4. The magneto-optical measurement apparatus according to claim 1, wherein the controller is configured to:
determine a first regression formula from values measured at the plurality of times under the positive magnetic field;
determine a second regression formula from values measured at the plurality of times under the negative magnetic field;
calculate a first value for the amount of light reflected under the positive magnetic field as of a specified time with the first regression formula;
calculate a second value for the amount of light reflected under the negative magnetic field as of the specified time with the second regression formula; and
determine the specific output value based on the first value and the second value.

5. The magneto-optical measurement apparatus according to claim 1, wherein the controller is configured to:
determine a third regression formula for the expected amount of light reflected when the magnetic film is not magnetized from the values measured at the plurality of times under the positive magnetic field and the values measured at the plurality of times under the negative magnetic field; and
determine the specific output value with the third regression formula.

6. The magneto-optical measurement apparatus according to claim 1,
wherein the controller is configured to blink the light source cyclically and perform synchronized measurement of the amount of light reflected by the thin-film sensor, and
wherein a cycle of the blink of the light source is shorter than a cycle of magnetic field reversal of the magnetic field generation device.

7. The magneto-optical measurement apparatus according to claim 6, wherein the controller is configured to light the light source with a constant current for a predetermined period before blinking the light source cyclically.

8. The magneto-optical measurement apparatus according to claim 1, wherein the magnetic field generation device is configured to generate the positive magnetic field and the negative magnetic field by changing direction of a constant current to be supplied to a coil.

9. The magneto-optical measurement apparatus according to claim 1, wherein the controller is configured to exclude data on the amount of reflected light measured within a predetermined period after the magnetic field generation device changes the direction of the magnetic field in determining the one or more regression formulae.

10. The magneto-optical measurement apparatus according to claim 1, wherein the controller is configured to measure the amount of light reflected by the thin-film sensor during a period where output of the light source is varying.

11. A magneto-optical measurement method comprising:
supplying a positive magnetic field and a negative magnetic field alternately to a magnetic film of a thin-film sensor to alternately cause positive magnetization and negative magnetization having equal magnitude but opposite directions in the magnetic film;
measuring the amount of light reflected by the thin-film sensor at a plurality of times under the positive magnetic field;
measuring the amount of light reflected by the thin-film sensor at a plurality of times under the negative magnetic field;
determining one or more regression formulae from the values measured under the positive magnetic field at the plurality of times and the values measured under the negative magnetic field at the plurality of times; and
determining a specific output value based on the one or more regression formulae.
